(19) United States
(12) Patent Application Publication
(10) Pub. No.: US 2010/0226076 A1
(43) Pub. Date: Sep. 9, 2010

(54) ELEMENT FIXING STRUCTURE

(75) Inventors: Cheng-Sheng Chiang, Taipei County (TW); Po-Fu Kuo, Taipei City (TW); Tsao-Yuan Fu, Taoyuan County (TW); Hui-Ju Hsu, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taoyuan (TW)

(21) Appl. No.: 12/542,665

(22) Filed: Aug. 17, 2009

(30) Foreign Application Priority Data
Mar. 6, 2009 (TW) 98203479

(51) Int. Cl. H05K 7/00

(52) U.S. Cl. 361/679.01

(57) ABSTRACT

The present invention relates to an element fixing structure. The element fixing structure includes a first fixing element, a second fixing element, a plurality of locking elements and at least two third fixing elements. The second fixing element has a locking structure, which has an inner thread. The locking element includes a screw. The third fixing element has at least one second passing slots. The first fixing element has at least two protrusion structures, wherein the protrusion structure has a first passing slot. The first fixing element, the second fixing element and at least two third fixing elements are locked with the locking structure by the locking element. Hence, the element fixing structure is used to reduce the numbers of the locking elements.

### CROSS-REFERENCE TO RELATED APPLICATION

This application claims the priority benefit of Taiwan application serial no. 98203479, filed on Mar. 6, 2009. The entirety of the above-mentioned patent application is hereby incorporated by reference herein and made a part of specification.

### BACKGROUND OF THE INVENTION

1. Field of Invention

The present invention relates to an element fixing structure.

2. Description of Related Art

Referring to FIG. 1, signals of a liquid crystal panel 11 of a liquid crystal display (LCD) 1 need to be controlled by a controlling circuit board 12, a printed circuit board 13 transmits the signals between the liquid crystal panel 11 and the controlling circuit board 12, and a converter circuit board 14 for light source driving is included in the LCD 1.

FIG. 1 is a partial schematic drawing of a conventional LCD 1. As shown in FIG. 1, surface protection structures 15 corresponding to the controlling circuit board 12, the printed circuit board 13 and the converter circuit board 14 protect the circuit boards from being touched and damaged during human assembling. The electromagnetic wave effect in LCD 1 is also reduced. Therefore, it is common for persons having ordinary skill in the art to use the locking method of screws 16 of the surface protection structures 15 respectively corresponding to the controlling circuit board 12, the printed circuit board 13, and the converter circuit board 14.

However, although the locking method of screws 16 of a surface protection structure 15 corresponding to the controlling circuit board 12, the printed circuit board 13 and the converter circuit board 14 can firmly lock the structure of a circuit board being accompanied with a surface protection structure 15 to the base board 17 by a plurality of screws 16, the locking design of many screws increases the usage of screws 16 and further reduces the assembling time and price competitiveness of LCD 1. Based on the above, the locking design of many screws is not good for the development of LCD 1. Therefore, LCD 1 needs an invention to save the usage of screws 16 and to ensure the strength of structure so as to reduce the producing cost and assembling time of LCD 1.

### SUMMARY OF THE INVENTION

As a result, the main object of the present invention is to propose an element fixing structure for reducing the producing cost and assembling time of the LCD.

The present invention discloses an element fixing structure including a first fixing element, a second fixing element, a plurality of locking elements, and a plurality of third fixing elements. The second fixing element has a locking structure including a rivet, a sheet metal convex hull, a sheet metal bridge, or a sheet metal burr, wherein the rivet, the sheet metal convex hull, the sheet metal bridge or the sheet metal burr have an inner thread. The locking element includes a screw. The third fixing element has a second passing slot, and includes a printed circuit board, a controlling circuit board or a converter circuit board. In addition, the directions of dispositions of a plurality of third fixing elements are toward on a parallel surface and a non-parallel surface. The first fixing element has a plurality of protrusion structures including a rivet, a sheet metal convex hull, or a sheet metal bridge and having a first passing slot, wherein the first passing slot is in a circular shape or a polygonal shape, and the first fixing element, the second fixing element and the plurality of third fixing elements are locked with the locking structure by the locking element respectively passing through the first passing slot, the second passing slot, and the locking structure. Accordingly, the objective of reducing the usage of locking elements is achieved through the design of the element fixing structure of the first fixing element, the second fixing element, and at least two of the third fixing elements.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a partial drawing of a conventional LCD.

FIG. 2 is a partial schematic drawing of a conventional LCD.

FIG. 3 is a partial schematic drawing of an LCD according to an embodiment of the present invention.

FIG. 4 is a 3D view of a first fixing element according to an embodiment of the present invention.

FIG. 5 is a partial schematic drawing of an LCD according to an embodiment of the present invention.

FIG. 6 is a partial schematic drawing of an LCD according to an embodiment of the present invention.

### DESCRIPTION OF EMBODIMENTS

Certain vocabularies are referred to specific elements in the specification and the claims. Persons having ordinary skill in the art should understand that manufacturer may use different terms on the same elements. The present specification and claims do not differentiate elements by different terms but by different functions. The wordings of “comprise” or “include” mentioned in the present specification and the claims are all open-ended wordings and should be explained as “include but not being limited”.

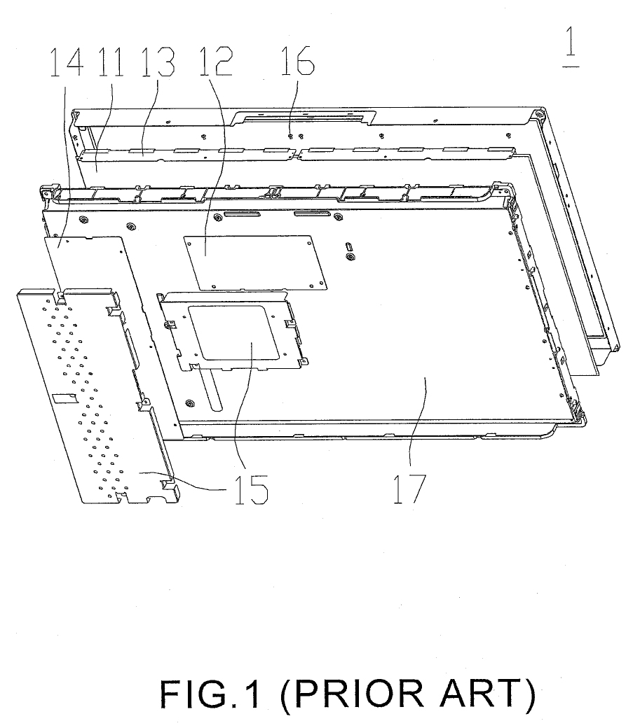

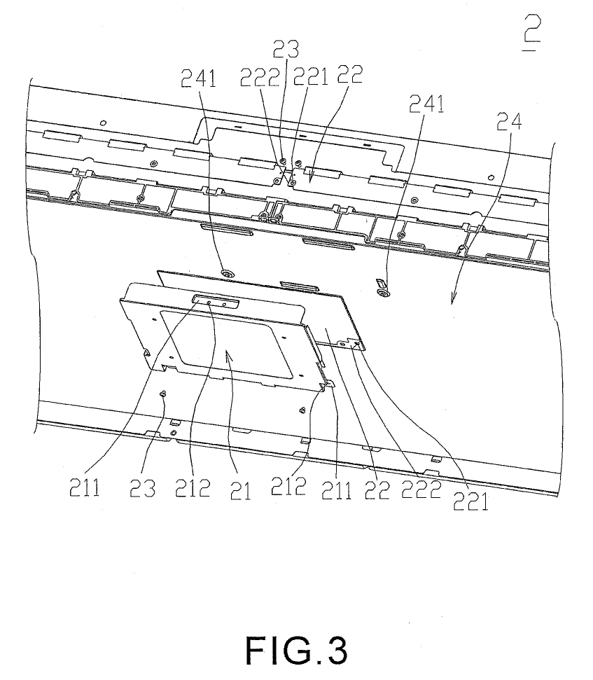

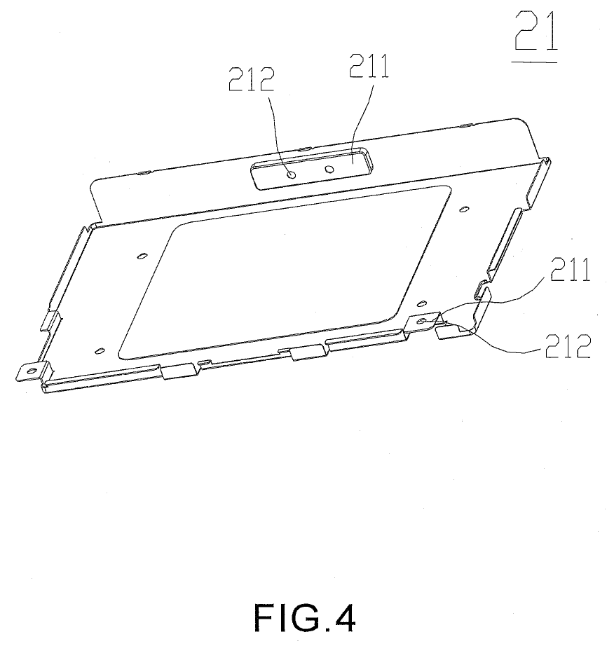

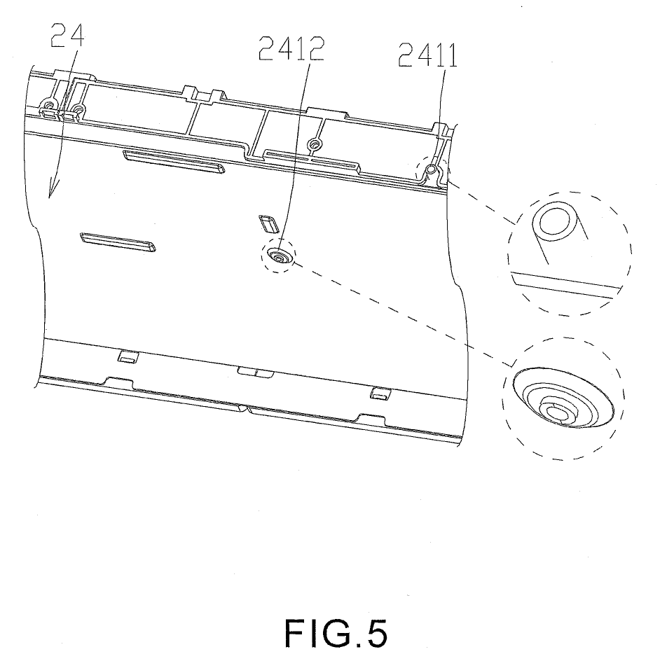

Referring to FIGS. 3 to 6, FIG. 3 is a partial schematic drawing of an LCD 2 according to an embodiment of the present invention. A first fixing element 21 of FIGS. 3 to 4 of an embodiment of the present invention is manufactured with a material of a sheet metal. The first fixing element 21 has a plurality of protrusion structures 211, wherein the plurality of protrusion structures 211 of the first fixing element 21 need to contact a plurality of third fixing elements 22. That is, one first fixing element 21 needs to contact at least two of the third fixing elements 22. The protrusion structures 211 can be designed with the structural model such as a rivet, a sheet metal convex hull, or a sheet metal bridge. The protrusion structures 211 can increase the spacing between the first fixing element 21 and the third fixing elements 22 to avoid the electric short-circuit or flashover caused by an over narrow spacing, and only the protrusion structures 211 of the first fixing element 21 contact a copper-coated area 222 near to a second passing slot 221 of the third fixing elements 22. The design of the protrusion structures 211 of the first fixing element 21 contacting the copper-coated area 222 near to the second passing slot 221 of the third fixing elements 22 can reduce the electromagnetic wave effect. The protrusion structures 211 have a first passing slot 212 designed in a circular or a polygonal shape, wherein the polygonal shape can be a shape with three or above angles such as triangular, quadrangular, or pentagonal. The design of the first passing slot 212 allows a locking element 23 effectively passing through the surface of the first fixing element 21, going down through the second passing slot 221 of the third fixing elements 22, reaching a locking structure 241 of a second fixing element 24, and locking an inner thread of the locking structure 241. The second fixing element 24 of the embodiment of the present invention is manufactured with a material of a sheet metal and has a plurality of locking structures 241 including a rivet 2411, a sheet metal convex hull 2412 in FIG. 5, or a sheet metal bridge and a sheet metal burr structure not shown in FIG. 5. The locking structures 241 increase the spacing between the second fixing element 24 and the surface of the third fixing elements 22 to avoid the electric short-circuit caused by an over narrow spacing between the second fixing element 24 and the third fixing element 22, and only the locking structures 241 of the second fixing element 24 contact the copper-coated area 222 near to the second passing slot 221 of the third fixing elements 22, which helps the elimination of the electromagnetic wave. The locking structures 241 have an inner thread. The design of the inner thread allows the locking element 23 effectively passing through the surface of the first fixing element 21, going down through the second passing slot 221 of the third fixing elements 22, and locking the inner thread of the locking structure 241. The locking elements 23 include screws 16 in prior art shown FIG. 1. The function of locking elements 23 is to provide the locking and fixing function for the first fixing element 21, the second fixing element 24 and the third fixing elements 22. The third fixing elements 22 include a printed circuit board 13, a controlling circuit board 12, or a converter circuit board 14 in prior art shown in FIG. 1.

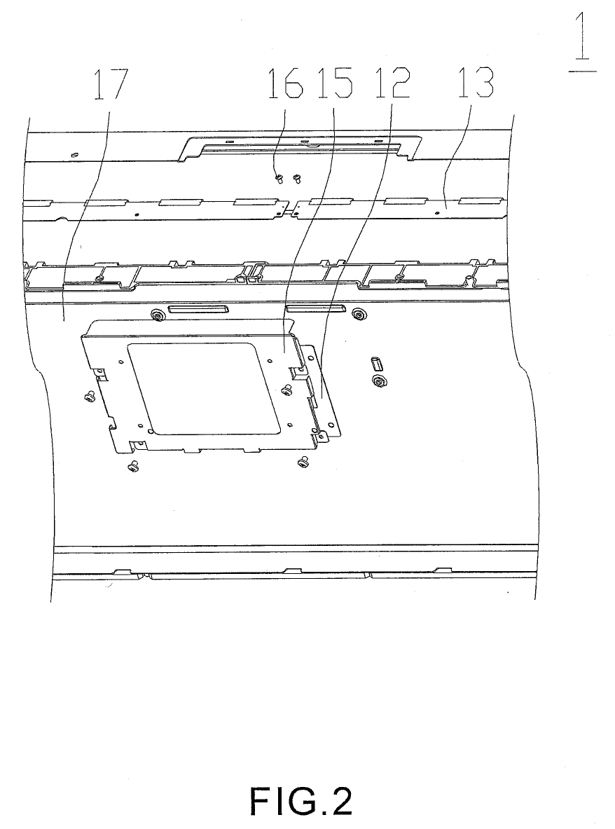

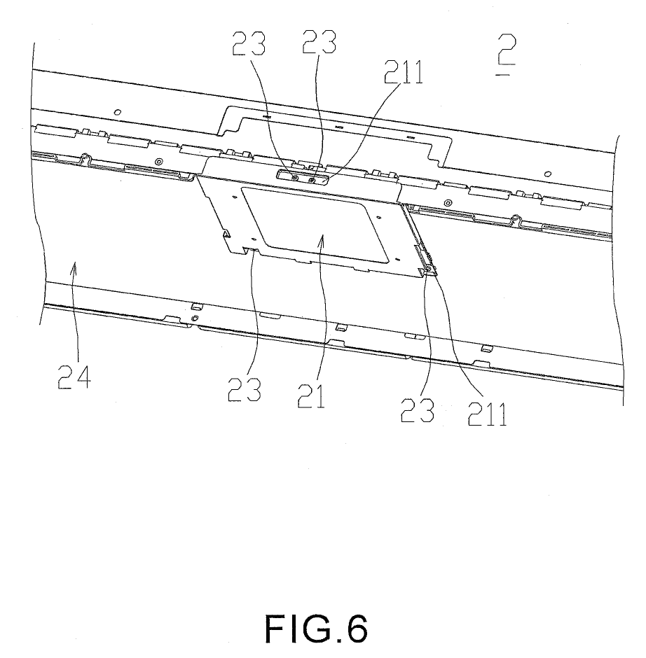

Referring to FIG. 6, FIG. 6 is a partial schematic drawing of an LCD 2 according to the embodiment of the present invention. The surface of the second fixing element 24 is disposed with two of the third fixing elements 22 (not shown in FIG. 6). The plurality of third fixing elements 22 of the present embodiment can be regarded as the printed circuit board 13 and the controlling circuit board 12 in FIG. 1. When one first fixing element 21 fixes two of the third fixing elements 22 and one second fixing element 24, the first passing slot 212 (not shown in FIG. 6) of the protrusion structure 211 of the first fixing element 21 touches and aligns the plurality of second passing slots 221 (not shown in FIG. 6) of two of the third fixing elements 22, and then the plurality of locking elements 23 pass through the first passing slot 212 of the protrusion structure 211 of the first fixing element 21 and the plurality of second slots 221 of two of the third fixing elements 22, and lock the inner thread of the locking structure 241 (not shown in FIG. 6) of the second fixing element 24. It takes four locking elements 23 to lock in the assembling process of FIG. 6. After comparing the design of a surface protection structure 15 locking a corresponding circuit board 7 and base board 17 in prior art of FIG. 2 with the design of the first fixing element 21 aligning and locking two of the third fixing elements 22 by the locking element 23, it is obvious that the embodiment of the present invention only needs four locking elements 23 to lock two of the third fixing elements 22 while in FIG. 2, six screws 16 are needed in FIG. 2 to lock the same positions so as to achieve the same effect. As a result, material cost and assembling time of the locking elements 23 are reduced in the embodiment of the present invention. In addition, after locking and fixing, the first fixing element 21 provides a firm fixing structure of above three positions and the electromagnetic wave is reduced by the contact of the third fixing elements 22, which results in better competitiveness of a product. Regarding the detailed assembling method of two of the third fixing elements 22 being disposed on the surface of the second fixing element 24, it is common knowledge for persons having ordinary skill in the art and is omitted here.

The embodiment described hereinbefore is chosen and described in order to best explain the principles of the invention and its best mode practical application. It is not intended to be exhaustive to limit the invention to the precise form or to the exemplary embodiments disclosed. Namely, persons skilled in the art are enabled to understand the invention through various embodiments with various modifications as are suited to the particular use or implementation contemplated. It is intended that the scope of the invention be defined by the claims appended hereto and their equivalents in which all terms are meant in their broadest reasonable sense unless otherwise indicated.

What is claimed is:

1. An element fixing structure, comprising:
a second fixing element having a plurality of locking structures;
a plurality of locking elements;
a plurality of third fixing elements having a plurality of second passing slots; and
a first fixing element having a plurality of protrusion structures, the plurality of protrusion structures having a first passing slot, wherein the first fixing element, the second fixing element and the plurality of third fixing elements are locked with the plurality of locking structures by the plurality of locking elements respectively passing through the plurality of first passing slots, the plurality of second passing slots, and the plurality of locking structures.

2. The element fixing structure according to claim 1, wherein the plurality of protrusion structures comprise a rivet.

3. The element fixing structure according to claim 2, wherein the first passing slot of the plurality of protrusion structures is in a circular shape or a polygonal shape.

4. The element fixing structure according to claim 1, wherein the plurality of protrusion structures comprise a sheet metal convex hull structure.

5. The element fixing structure according to claim 4, wherein the first passing slot of the plurality of protrusion structures is in a circular shape or a polygonal shape.

6. The element fixing structure according to claim 1, wherein the plurality of protrusion structures comprise a sheet metal bridge structure.

7. The element fixing structure according to claim 6, wherein the first passing slot of the plurality of protrusion structures is in a circular shape or a polygonal shape.

8. The element fixing structure according to claim 1, wherein the locking structure of the second fixing element comprises a rivet having an inner thread.

9. The element fixing structure according to claim 1, wherein the locking structure of the second fixing element comprises a sheet metal convex hull having an inner thread.

10. The element fixing structure according to claim 1, wherein the locking structure of the second fixing element comprises a sheet metal bridge having an inner thread.

11. The element fixing structure according to claim 1, wherein the locking structure of the second fixing element comprises a sheet metal burr having an inner thread.

12. The element fixing structure according to claim 1, wherein the locking element comprises a screw.

13. The element fixing structure according to claim 1, wherein the third fixing element comprises a printed circuit board.

14. The element fixing structure according to claim 1, wherein the third fixing element comprises a controlling circuit board.

15. The element fixing structure according to claim 1, wherein the third fixing element comprises a converter circuit board.
